(19) United States
(12) Patent Application Publication
(10) Pub. No.: US 2008/0179720 A1
(43) Pub. Date: Jul. 31, 2008

(54) Lead frame for chip packages with wire-bonding at single-side pads

(75) Inventors: Wen-Jeng Fan, Hsinchu (TW); Yi-Ling Liu, Hisnchu (TW)

Correspondence Address: TROXELL LAW OFFICE PLLC, SUITE 1404, 5205 LEESBURG PIKE, FALLS CHURCH, VA, 22041, US

(73) Assignee: POWERTCH TECHNOLOGY INC.

(21) Appl. No.: 11/657,716

(22) Filed: Jan. 25, 2007

(51) Int. Cl. H01L 23/495

(52) U.S. Cl. 257/666; 257/E23.031

(57) ABSTRACT

A chip package and a lead frame used in the chip package are disclosed. The lead frame includes a plurality of first side leads and a plurality of second side leads where the first side leads have a plurality of first bent leads extending from a first edge and the second side leads have a plurality of second bent leads extending from a second edge. The inner ends of the first bent leads and the inner ends of the second bent leads are facing to a third edge between the first and second edges and are connected to the lead frame. Therefore, the lengths of the first side leads are equal and symmetrical to the ones of the second side leads without any suspended long leads for chip attachment. The chip package is most suitable for packaging chips with bonding pads on one single side.

### FIELD OF THE INVENTION

The present invention relates to lead frames for chip packages, and more particularly, to lead frames for chip packages for chips with wire-bonding at single-side pads.

### BACKGROUND OF THE INVENTION

A lead frame has a plurality of metal leads to transmit signals from a chip. In a known type of lead frame, leads also can replace a die pad for die attachment. Because of different layouts of bonding pads of a chip, the shapes of the leads of a lead frame have to change accordingly. Normally, for a chip with peripheral bonding pads, a die pad of a lead frame is necessary for die attachment. But for a chip with central bonding pads, the extended inner leads of a lead frame are used for die attachment. However, for a chip with bonding pads on singe side, the leads of the corresponding lead frame are asymmetrical leading to insufficient strength of the leads to support the attached die.

Shown in FIG. 1 is a disclosed chip package for chips with bonding pads on one single side. The chip package primarily includes an asymmetrical lead frame with a plurality of first leads 110 on one side and with a plurality of second leads 120 on the opposite side, a chip 210 with bonding pads 211 on one side close to the second leads 120, and an encapsulant 220. As shown in FIG. 3, the lengths of the first leads 110 are much longer than the ones of the second leads 120 so that the chip 210 is attached to the first leads 110. As shown in FIG. 2, the bonding pads 211 are disposed on one side of the active surface of the chip 210. Referring to the FIG. 1, after attaching the chip 210 to the first leads 110, the bonding pads 211 are adjacent to the second leads 120 for being electrically connected to the inner leads 111 of the first leads 110 and to the inner leads 121 of the second leads 120 by a plurality of bonding wires 230. Then the chip 210, the inner leads 111 of the first leads 110, the inner leads 121 of the second leads 120, and the bonding wires 230 are encapsulated by the encapsulant 220. As shown in FIG. 3, since the lengths of the inner leads 111 of the first leads 110 are much longer than the ones of the inner leads 121 of the second leads 120, therefore, the inner leads 111 of the first leads 110 are suspended before encapsulation leading to insufficient strength to support the attached chip 210. Two major problems will be encountered. One is the shaking of the bonding wires 230 during wire bonding on the first leads 110 and the other one is the shifting of the chip 210 during the encapsulation of the encapsulant 220.

### SUMMARY OF THE INVENTION

The main purpose of the present invention is to provide a lead frame for a chip package to resolve the shaking of bonding wires during wire bonding processes and the shifting of the chip during encapsulation causing by the suspended and long inner leads for a chip with bonding pads on one side.

The second purpose of the present invention is to provide a lead frame for a chip package to attach and to support a larger chip with bonding pads on one side.

According to the present invention, a first edge, a second edge, and a third edge are defined in the packaging unit of a lead frame for chip packages where the first edge is parallel to the second edge and the third edge is formed between the first edge and the second edge. The lead frame includes a plurality of first leads and a plurality of second leads where the first leads extend from the first edge with a plurality of first bent leads and the second leads extend from the second edge with a plurality of second bent leads. Moreover, a plurality of inner ends of the first bent leads and a plurality of inner ends of the second bent leads are bent toward the third edge and are connected to the lead frame.

### DESCRIPTION OF THE DRAWINGS

FIG. 1 shows a cross-sectional view of a conventional chip package.

FIG. 2 shows a top view of a chip with bonding pads on one single side.

FIG. 3 shows a top view of asymmetrical leads of the lead frame for a corresponding conventional chip package.

FIG. 4 shows a top view of a lead frame for carrying a chip with bonding pads on one single side according to the first embodiment of the present invention.

FIG. 5 shows a partially enlarged top view of the lead frame after die attaching and wire bonding according to the first embodiment of the present invention.

FIG. 6 shows a cross-sectional view of a chip package utilizing the lead frame according to the first embodiment of the present invention

FIG. 7 shows a top view of a lead frame for carrying a chip with bonding pads on one single side according to the second embodiment of the present invention.

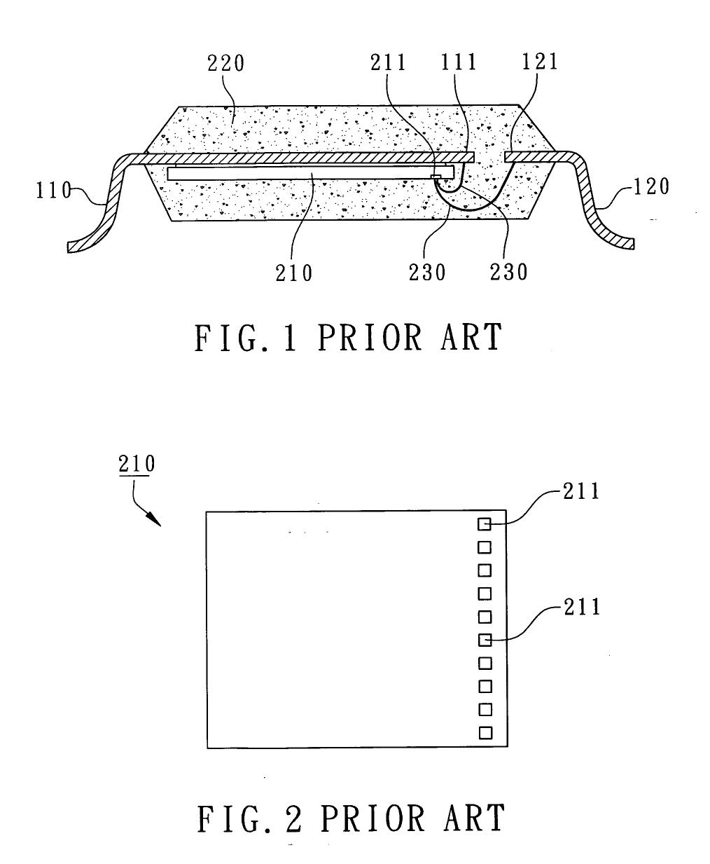

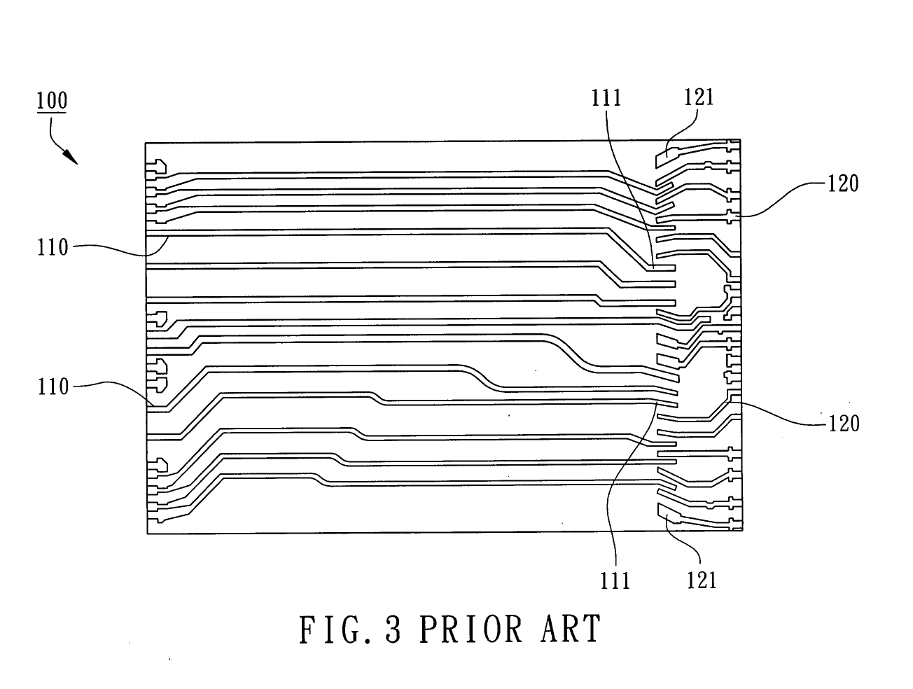

### DETAIL DESCRIPTION OF THE INVENTION

Please refer to the attached drawings, the present invention will be described by means of embodiment(s) below.

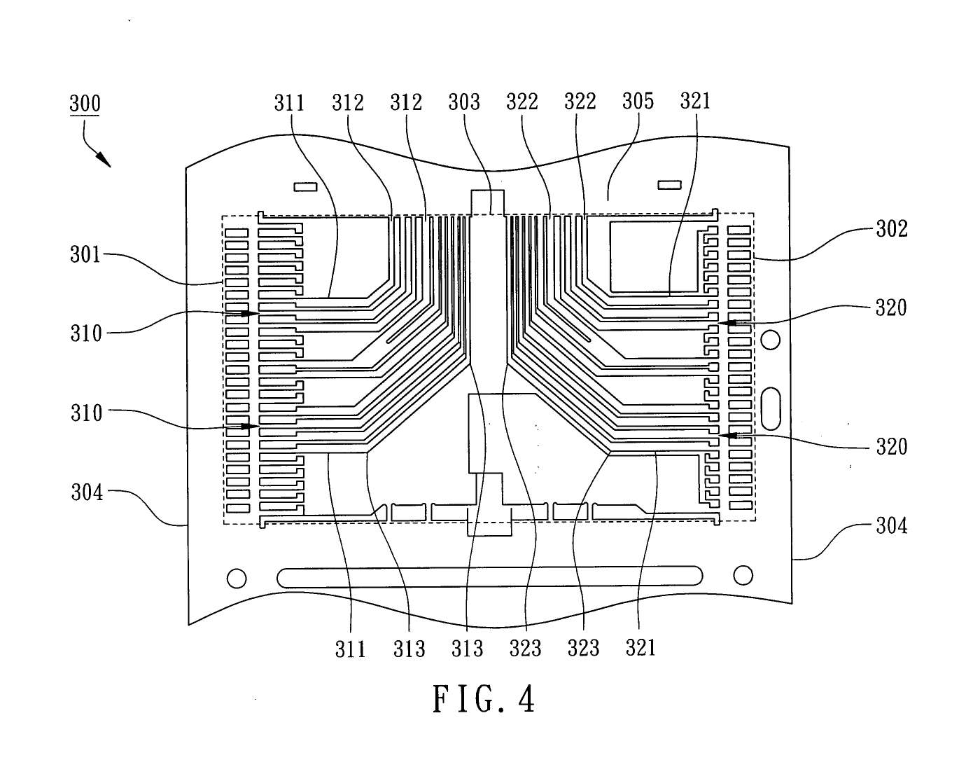

According to the first embodiment of the present invention, a lead frame for chip packages is revealed. As shown in FIG. 4, a first edge 301, a second edge 302, and a third edge 303 are defined in one of the packaging units of a lead frame 300 where the first edge 301 is parallel to the second edge 302 and the third edge 303 is formed between and vertical to the first edge 301 and the second edge 302.

The lead frame 300 includes a plurality of first leads 310 and a plurality of second leads 320 where the first leads 310 inwardly extend from the first edge 301 with a plurality of first bent leads 311 and the second leads 320 inwardly extend from the second edge 302 with a plurality of second bent leads 321. The inner ends 312 of the first bent leads 311 and the inner ends 322 of the second inner leads 321 are converged and bent toward the third edge 303 and are connected to the lead frame 300. Therefore, the shaking of the bonding wires during wire bonding processes and the shifting of the chip during encapsulation causing by the suspended and long inner leads of a conventional lead frame for a chip with bonding pads on one single side are eliminated. In the present embodiment, the lead frame 300 has two edge rails 304 disposed on the external sides of the first edge 301 and the second edge 302, i.e., the longest external portions of the lead frame 300 for handling and transportation. A plurality of frame bars 305 are formed between the edge rails 304 to separate the packaging units. In different embodiments, the external parts along the first edge 301 and the second edge 302 of the lead frame 300 can be the frame bars.

To be more specific, the inner ends 312 of the first bent leads 311 and the inner ends 322 of the second bent leads 321 are connected to the frame bar 305 between the two edge rails 304 of the lead frame 300. Preferably, the inner ends 312 of the first bent leads 311, the inner ends 322 of the second bent leads 321, and the connected frame bar 305 are an integral connection to reduce the cost.

Again as shown in FIG. 4, each of the first bent leads 311 and the second bent leads 321 has two 45° horizontally bent points 313 and 323 so that the inner ends 312 of the first bent leads 311 and the inner ends 322 of the second inner leads 321 are disposed at the third edge 303 to reduce the parasitic effects. Furthermore, as shown in FIG. 6, the first bent leads 311 and the second bent leads 321 are coplanar without any vertical bending nor deformation.

Therefore, the lead frame 300 of the present invention is suitable for packaging chips with bonding pads on one single side to resolve the shaking of the bonding wires during wire bonding processes and the shifting of the chip during encapsulation of conventional chip packages.

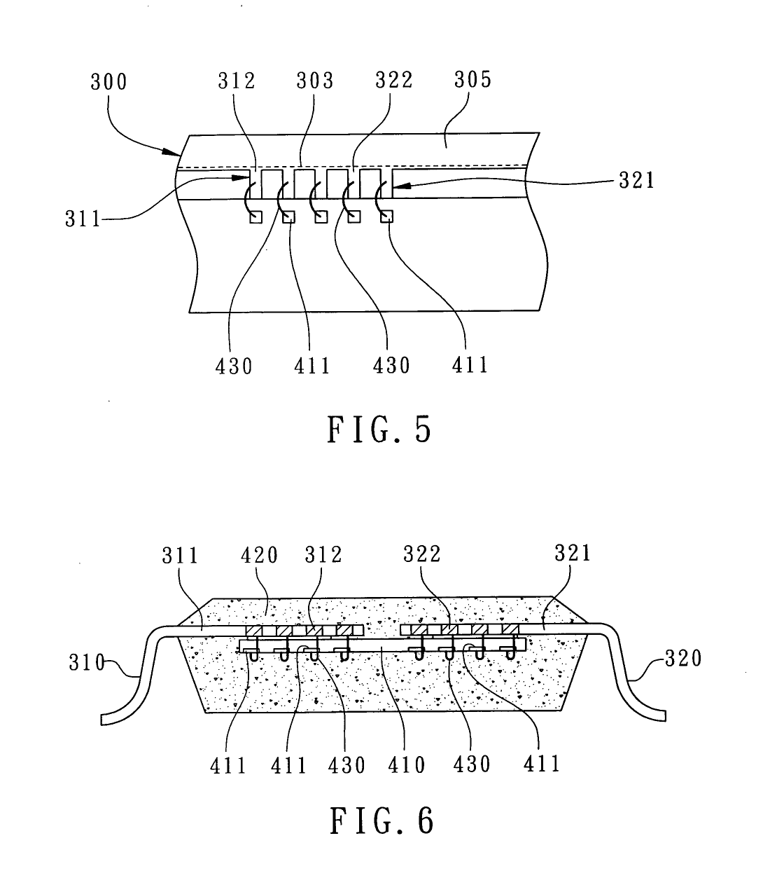

As shown in FIG. 6, a chip package utilizing the lead frame 300 primarily includes a chip 410, an encapsulant 420, and a plurality of first leads 310 and a plurality of second leads 320 of the lead frame mentioned above where the chip 410 has a plurality of bonding pads 411 disposed on one single side facing the third edge, as shown in FIG. 5. The chip package further includes a plurality of bonding wires 430 for electrically connecting the bonding pads 411 of the chip 410 to the inner ends 312 of the first bent leads 311 and to the inner ends 322 of the second bent leads 321. As shown in FIG. 5, since the inner ends 312 of the first bent leads 311 and the inner ends 322 of the second bent leads 321 are still connected to the frame bar 305 of the lead frame 300 during wiring bonding. Therefore, there is no shaking issue of bonding wires during wire bonding processes so that the bonding wires 430 can be firmly bonded to the inner ends 312 of the first bent leads 311 and to the inner ends 322 of the second bent leads 321. Furthermore, there is also no shifting issue of the chip 410 during encapsulation of encapsulant 420.

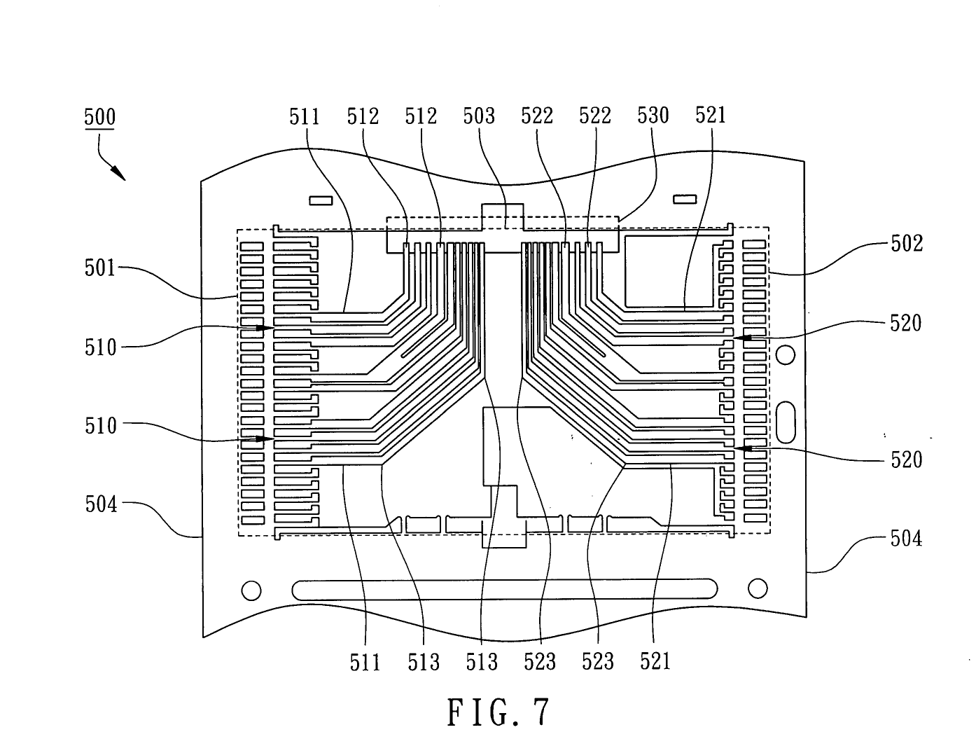

According to the second embodiment of the present invention, another lead frame of a chip package is revealed in FIG. 7 where a first edge 501, a second edge 502, and a third edge 503 are defined in one of the packaging units of the lead frame 500. The first edge 501 is parallel to the second edge 502 and the third edge 503 is formed between the first edge 501 and the second edge 502.

The lead frame 500 includes a plurality of first inner leads 510 and a plurality of second inner leads 520 where the first inner leads 510 extend from the first edge 501 with a plurality of first bent leads 511 and the second inner leads 520 extend from the second edge 502 with a plurality of second bent leads 521. Since the inner ends 512 of the first bent leads 511 and the inner ends 522 of the second bent leads 522 are converged and face the third edge 503 and are connected to the lead frame 500, therefore, there is no shaking issue of the bonding wires during wire bonding processes nor shifting issue of the chip during encapsulation caused by suspended and long inner leads of conventional chip packages. The lead frame 500 further includes an attaching film 530 such as PI to connect the inner ends 512 of the first bent leads 511 and the inner ends 522 of the second bent leads 521 to the lead frame 500 to resolve the shaking of the bonding wires during wire bonding processes and the shifting of the chip during encapsulation of conventional chip packages. Furthermore, in the present embodiment, the lead frame 500 has edge rails 504 disposed on the external sides of the first edge 501 and the second edge 502, i.e., the longest external portions of the lead frame 500 for handling and transportation.

As shown in FIG. 7 again, each of the first bent leads 511 and the second bent leads 521 have two 45° horizontally bent points 513 and 523 so that the inner ends 512 of the first bent leads 511 and the inner ends 522 of the second inner leads 521 are disposed at the third edge 503 to reduce the parasitic effects.

The above description of embodiments of this invention is intended to be illustrative and not limiting. Other embodiments of this invention will be obvious to those skilled in the art in view of the above disclosure.

What is claimed is:

1. A lead frame for chip packages with a first edge, a second edge, and a third edge defined in a package unit, wherein the first edge is parallel to the second edge and the third edge is formed between the first edge and the second edge, the lead frame comprising:
a plurality of first side leads having a plurality of first bent leads extending from the first edge; and
a plurality of second side leads having a plurality of second bent leads extending from the second edge;
wherein a plurality of inner ends of the first bent leads and a plurality of inner ends of the second bent leads are both bent toward the third edge and are connected to the lead frame.

2. The lead frame of claim 1, further comprising a frame bar between two edge rails of the lead frame, connecting the inner ends of the first bent leads and the inner ends of the second bent leads.

3. The lead frame of claim 2, wherein the inner ends of the first bent leads, the inner ends of the second bent leads, and the connected frame bar are an integral connection.

4. The lead frame of claim 1, wherein the inner ends of the first bent leads and the inner ends of the second bent leads are integrally connected to the lead frame.

5. The lead frame of claim 4, further comprising an attaching film connecting the inner ends of the first bent leads and the inner ends of the second bent leads to the lead frame.

6. The lead frame of claim 1, wherein each of the first bent leads and the second bent leads has two 45° horizontally bent points.

7. The lead frame of claim 1, wherein the first bent leads and the second bent leads are coplanar without any vertical bending nor deformation.

8. A chip package comprising a chip, an encapsulant, and a plurality of first side leads and a plurality of second side leads as claimed in claim 1, where the chip has a plurality of bonding pads adjacent to the third edge.

9. The chip package of claim 8, further comprising a plurality of bonding wires electrically connecting the bonding pads to the inner ends of the first bent leads and to the inner ends of the second bent leads.
